(19) United States
(12) Patent Application Publication
(10) Pub. No.: US 2012/0298205 A1
(43) Pub. Date: Nov. 29, 2012

(54) Method and apparatus for the mechanical filtration of particles in discrete flow microfluidic devices

(76) Inventors: Michael John Schertzer, Milton (CA); Ridha Ben Mrad, Toronto (CA); Pierre Edward Sullivan, Toronto (CA)

(21) Appl. No.: 13/305,507

(22) Filed: Nov. 28, 2011

Related U.S. Application Data
(60) Provisional application No. 61/417,828, filed on Nov. 29, 2010.

(51) Int. Cl. B81B 1/00; B01L 3/00

(52) U.S. Cl. 137/1; 422/502; 204/601

(57) ABSTRACT

A method and apparatus for moving droplets passed a porous obstructions in microfluidic devices is presented. The invention describes the process of using of an enabling droplet to allow a droplet to pass an obstruction. The enabling droplet and the unfiltered droplet approach the obstruction from opposite sides, merge together within the obstruction, and the interface on the enabling side of the droplet is actuated to pull fluid through the obstruction. This technique was successful for filters with pore sizes between 2 μm and 72 without the use of surfactants. This invention can (1) move droplets past physical obstructions, (2) allow fluid within a particle to pass an obstruction while limiting the motion of man-made or biological particles within the droplet, (3) sort particles based on size in droplet-based microfluidic devices, or (4) provide an interface between continuous and discrete flow regions on a microfluidic device.

This application claims the benefit of U.S. Provisional Application No. 61/417,828 filed Nov. 29, 2010

### BACKGROUND OF THE INVENTION

Droplet based microfluidic devices have recently been introduced as tools to increase throughput and reduce operating costs of biological protocols [i.e. 1-5]. Device platforms have been introduced to manipulate droplets by chemical [2], thermal [2], acoustic [3], and electrical [4] means. In many biological protocols, specific reactions are used to bind target species to solid surfaces. In a microfluidic device, more flexibility can be achieved by performing these reactions on particles suspended in the flow instead of stationary surfaces. This can be achieved by binding the target antibodies to particles suspended within the droplet [i.e. 10-12]. Although this solution provides devices with more flexibility, it also requires a means for particle manipulation in microfluidic devices [i.e. 10-14, P4-P8]. Electrowetting on dielectric (EWOD) is one example of a droplet based microfluidic actoator. These devices apply asymmetric electric fields to manipulate droplets with diameters on the order of 1-2 mm that are confined between parallel plates separated by 50-150 μm (˜40-500 mL) [4-7, P1-P3]. These devices have demonstrated the ability to create, move, split, and mix droplets of fluid. They also have low power consumption, high reversibility, and wide applicability to different fluids [4-8]. A comprehensive review of these devices can be found in [9].

Immonoassays are one application that makes use of particle manipulation in microfluidic devices. Here, required reactions have been performed on the surface of particles held in solution [10-13]. This technique has been applied to both continuous [10] and droplet based [11-12] microfluidic devices. The separation of the particles from any unbound material present in the droplet is necessary for this application. Particles can be collected in a specific location in the droplet using a variety of forces [11-14,P4-P9]. The fluid in the droplet can then be manipulated to wash the particles of unbound material. In EWOD devices, the immobilization and filtration of particles in droplets is most commonly achieved through the use of electrophoresis (or dielectrophoresis) [13,P6,P7] or magnetic forces [11,12,P4,P5]. Electrophoretic forces are used to manipulate particles suspended in a droplet in [13]. Here, the hydrophobic coating on the upper substrate of the EWOD device was partially removed so that an electric field could be applied across the diameter of the droplet. The electric field applies a force on the particles so that positively charged particles are drawn to the negative electrode and vice versa. A similar method is described in [P7] which proposed a two stage dielectrophoresis system where the first stage creates and manipulates droplets and the second manipulates particulate inside the droplet. In [11,12,P4,P5] droplets are seeded with magnet particles and a magnet is placed beneath a portion of an EWOD device. When a particle laden droplet passes by the magnetized area, the particles are immobilized. The original droplet can then be diluted or removed so that unbound material is washed away from the particles. More comprehensive methods of particle manipulation in microfluidic devices are presented in [P6] which proposes the use of electrophoretic, dielectrophoretic, electrostatic, or electrowetting on dielectric forces as a means of particle manipulation.

Mechanical filtration of particles has been used in continuous flow microfluidic devices [10,14,P4,P9,P10], but not in droplet based microfluidic devices. In the continuous flow immunoassay device presented in [10], an obstruction with a pore size of 20 μm was placed in the flow. This obstruction was used to block 90 μm particles while allowing fluid to pass. A similar method was used in the continuous flow device presented in [14,P10]. In this case, white blood cells were filtered from a continuous flow sample of whole blood using an obstruction with a pore size of approximately 3.5 μm. Mechanical filtration of particles has not yet been performed in EWOD devices.

Although it is less common, mechanical forces have also been used to manipulate particles in microfluidic devices [10,14,P4,P9]. In the continuous flow immunoassay device presented in [9], an obstruction with a pore size of 20 μm was placed in the flow. This obstruction was used to block 90 μm particles while allowing fluid to pass. A similar method was used in the continuous flow device presented in [14]. In this case, white blood cells were filtered from a continuous flow sample of whole blood using an obstruction with a pore size of approximately 3.5 μm. Mechanical filtration of particles has not yet been performed in droplet based microfluidic devices.

A scheme for the mechanical filtration of particles in droplet based microfluidic devices has been proposed by [P4]. In this scheme, a physical obstruction protrudes from either the upper or lower substrate. A particle laden droplet on one side of the obstruction is pulled passed the obstruction using EWOD. Since this obstruction partially blocks the cross sectional area that the droplet passes through, any particles within the droplet that are larger than the pore size would be filtered out by the obstruction. This method of particle filtration was also proposed in [P9]. Here the obstruction was also claimed to be used as a bridge between continuous and droplet based flows. A continuous flow would be present on one side of the obstruction, but droplets could be drawn passed that obstruction using EWOD to create droplet based flow. Although claims were made in both [P4] and [P9], the inventors here could not find evidence of experimental results in patent databases or scientific literature showing that this method of mechanical filtration in droplet based flows is feasible. Experimental tests performed by the current inventors show that it is was not possible to draw a droplet past a physical obstruction in the manner described in [P4, P9] with a comb type filter at pore sizes examined here. Analytical results show that the maximum pore size for the filtration method shown in [P4,P5] is half the gap distance. This would make filtration of small particles, such as animal cells, impractical. This was the impetus for the invention that we present here.

### JOURNAL ARTICLES REFERENCED

[1] Wheeler A. R., Moon H., Kim C. J., Loo J. A., Garell R. L., Electrowetting-Based Microfluidics for Analysis of Peptides and Proteins by Matrix-Assisted Laser Desorption/Ionization Mass Spectrometry. Analytical Chemistry, 2004, 76 4833-4838
[2] Brochard F., Motions of Droplets on Solid Surfaces Induced by Chemical or Thermal Gradients, Langmuir 1989, 5, 432-438
[3] Wixforth A., Strobl C., Gauer C., Toegl A., Scriba J., Guttenberg Z. v., Acoustic manipulation of small droplets, Anal Bioanal Chem, 2004, 379, 289-991
[4] Washizu M., Electrostatic Actuation of Liquid Droplets for Microreactor Applications, IEEE Transactions on Industry Applications, 1998, v 34 n 4, 732-737
[5] Cho S, Moon H, Kim C. J., Creating, Transporting, Cutting, and Merging Liquid Droplets by Electrowetting-Based Actuation for Digital Microfluidic Circuits, Journal of Microelectromechanical Systems, 2003, 12, 70-79
[6] Ren H, Fair R, Pollack M, Shaughnessy E, Dynamics of electro-wetting droplet transport, Sensors and Actuators B, 2002, 87, 201-206
[7] Chatterjee D., Hetayothin B., Wheeler A. R., King D., Garrell R. L., Droplet-based microfluidics with non-aqueous solvents and solutions, Lab on a Chip, 2006, 199-206
[8] Pollack M, Electrowetting-based microactuation of droplets for digital microfluidics, Ph.D. Thesis, Duke University, North Carolina, 1999
[9] Berthier J., Microdrops and Digital Microfluidics, William Andrew Pub. Norwich, N.Y., 2008
[10] Endo T., Okuyama A., Matsubara Y., Nishi K., Kobayashi M., Yamamura S., Morita Y., Takamura Y., Mizukambi H., Tamiya E., Fluorescence-based assay with enzyme amplification on a micro-flow immunosensor chip for monitoring coplanar polychlorinated biphenyls, Analytica Chimica Acta, 2005, 1, 7-13
[11] Sista R., Hua Z., Thwar P., Sudarsan A., Srinivasan V., Eckhardt A., Pollack M., Pamula V., Development of a digital microfluidic platform for point of care testing, Lab on a Chip, v. 8, 2008, v. 8, 2091-2104
[12] Sista R., Eckhardt A., Srinivasan V., Pollack M., Palanki S, Pamula V., Heterogeneous immunoassays using magnetic beads on a digital microfluidic platform, Lab on a Chip, 2008, 8, 2188-2196
[13] Cho S. K., Kim C. J., Particle separation and concentration control for digital microfluidics. Proceedings IEEE Sixteenth Annual International Conference on Micro Electro Mechanical Systems, 2003, 686-689
[14] Wilding P., Kricka L. J., Cheng J., Hvichia G., Shoffner M. A., Fortina P.; Integrated Cell Isolation and Polymerase Chain Reaction Analysis Using Silicon Microfilter Chambers, Analytical Biochemistry, 1998, 257, 95-100
[15] Schertzer M. J., Ben Mrad R., Sullivan P. E., Using capacitance measurements in EWOD devices to identify fluid composition and control droplet mixing; Sensors & Actuators: B. Chemical, 2010, 145; p 340-347
[16] Schertzer M. J., Gubarenko S. I., Ben Mrad R., Sullivan P. E. An empirically validated analytical model of droplet dynamics in EWOD devices; Langmuir 2010, v26, n 24; pp 19230-19238

### PATENTS AND PATENT APPLICATIONS REFERENCED

[P1] Pamula et al. 2005, Apparatus for Manipulating Droplets by Electrowetting-Based Techniques. U.S. Pat. No. 6,911,132 B2 Issued Jun. 28, 2005
[P2] Haluzak et al. 2006, Electro-wetting on dielectric for Pin-Style Fluid Delivery, U.S. Pat. No. 7,780,830 Issued Aug. 24, 2010
[P3] Takenaka et al. 2008, Actuator for Manipulation of Liquid Droplets, U.S. Pat. No. 7,735,967 B2 Issued Jun. 15, 2010
[P4] Pamula et al. 2008, Droplet Based Surface Modification and Washing. U.S. Pat. No. 7,439,014 Issued Oct. 21, 2008
[P5] Shah G. J., Kim C. J., 2009, Method for Using Magnetic Particles in Droplet Microfluidics. U.S. Pat. No. 0,283,407 Issued Nov. 19, 2009.
[P6] Medoro et al. 2009, Method and Apparatus for the Manipulation and/or Detection of Particles. U.S. patent application Ser. No. 20,090,205,963 Issued Aug. 20, 2009
[P7] Kanagasabapathi et al. 2010, Integrated Microfluidic Transport and Sorting System. U.S. Pat. No. 7,658,829 Issued Feb. 9, 2010
[P8] Pollack et al. 2008, Droplet Based Particle Sorting U.S. patent application Ser. No. 20,080,053,205 Issued Mar. 6, 2008
[P9] Pamula et al. 2010, Droplet Actuator Loading and Target Concentration, U.S. patent application Ser. No. 20,100,062,508 Issued Mar. 11, 2010.
[P10] Wilding P., Kricka L. J., 2001, Mesoscale sample preparation device and systems for determination and processing of analytes. U.S. Pat. No. 6,184,029 B1 Issued Feb. 6, 2001

### BRIEF DESCRIPTION OF THE INVENTION

In one embodiment of the invention, a droplet is pulled through a physical obstruction in an electrowetting on dielectric (EWOD) device using an enabling droplet. It should be understood that the process proposed in the invention is not limited to EWOD and can be achieved using other actuation methods (i.e. surface acoustic waves, electrostatic actuation, electroosmotic flow, etc.). In one example, the obstruction could be coated with at least one reagent that could react with at least one reagent in the droplet. It should be understood that this is not the only application for this embodiment of the invention. The device would consist of an array of at least two electrodes, with the obstruction oriented to block the motion of the droplet along the array of electrodes (FIG. 3). Here, the droplet is confined between two substrates with the electrode array patterned on one substrate, and a ground electrode patterned on another. The obstruction is permeable with a pore size less than or equal to the spacing between the two substrates (FIG. 2). In one example of the device, the obstruction is created using patterned photoresist (SU-8), but it should be understood that the obstruction can be fabricated from a number of materials, including but not limited to polymers (i.e. PDMS, Su-8), ceramic materials and sintered metals, the obstruction could also be etched out of the substrate of the device (i.e. glass, silicon, quarts, lithium niobate, etc.). Initially, two droplets are placed in the device on opposite sides of the obstruction (FIG. 3). The device may or may not include circuitry to control the manipulation of droplets in the device. Both droplets are manipulated so they move toward the physical obstruction from opposite sides. In the experiments performed by the inventors, it was not possible to pull the unfiltered droplet through the obstruction using EWOD forces. Instead, the enabling droplet pulls the other droplet through the obstruction. Provided the width of the obstruction is less than twice the deformation of the interface in the opening in the obstruction, the portion of the leading interfaces that penetrate into the pore of the obstruction will merge together (FIGS. 3-5). If a small channel exists in the obstruction (i.e. FIG. 3) the air between the droplets will escape from the pore, and the unfiltered and enabling droplets will merge (FIGS. 4,5). Once these droplets have merged, the amalgamated droplet can be pulled through the obstruction by applying an EWOD force on the interface of the amalgamated droplet on the enabling side of the obstruction (FIG. 4). Once the process is complete, the entire amalgamated droplet can be pulled through the obstruction (FIG. 4), or part of it can be separated on the enabling side of the obstruction and manipulated as required.

In another embodiment of the invention, a droplet is pulled through a physical obstruction in a droplet based microfluidic device. Again, the obstruction could be coated with at least one reagent which would react with at least one reagent in the droplet, but other motivations exist for pulling a droplet through an obstruction. The device would consist of an array of at least two electrodes, with the obstruction oriented to block the motion of the droplet along the array of electrodes. Here, the droplet is unconfined, but sits atop a substrate patterned with an array of electrodes that act as both actuation and ground electrodes. The obstruction is permeable with a pore size less than or equal to the droplet diameter. The height of the obstruction is sufficient to prevent fluid from passing by travelling over the obstruction. The obstruction can be fabricated from a number of materials, including but not limited to polymers (i.e. PDMS, Su-8), ceramic materials and sintered metals, the obstruction could also be etched out of the substrate of the device (i.e. glass, silicon, quarts, lithium niobate, etc.). Initially, two droplets exist on opposite sides of the obstruction (FIG. 3-5). The device can also include circuitry to automate droplet manipulationDroplets are manipulated so they move toward the obstruction from opposite sides. Again, one of the droplets enables the other to pass by pulling it through the obstruction. Provided that the width of the obstruction is less than twice the deformation of the interface in the opening in the obstruction, the droplets will merge within the pore of the obstruction. Once these droplets have merged, the amalgamated droplet can be pulled through the obstruction. Once the process is complete, the droplets can be separated on the enabling side of the obstruction and manipulated a required.

In another embodiment of the invention, the physical obstruction is used as a means of filtering particles from droplets in an electrowetting on dielectric (EWOD) device. The device consists of an array of at least two electrodes, with the obstruction oriented to block the motion of the droplet along the array of electrodes (FIG. 3). Here, the droplet is confined between two substrates with the electrode array patterned on one substrate, and a ground electrode patterned on another. The obstruction is permeable with a pore size less than or equal to the spacing between the two substrates. The obstruction can be fabricated from a number of materials, including but not limited to polymers (i.e. PDMS, Su-8), ceramic materials and sintered metals, the obstruction could also be etched out of the substrate of the device (i.e. glass, silicon, quarts, lithium niobate, etc.). Initially, an unfiltered droplet exist on one side of the obstruction and an enabling droplet exists on the other side of the obstruction (FIG. 5 a). The unfiltered droplet is seeded with at least one type of particle whose size is larger than the pore size in the obstruction (FIGS. 5-7). The particle could be fabricated material (i.e. metal, polymer, glass particles etc.) or biological (i.e. cells, single or multiple cell organisms, protein chains, etc.) in nature. The device may also include control circuitry for droplet manipulation. The unfiltered and enabling droplets are manipulated toward the physical obstruction from opposite sides. In the experiments performed by the inventors, it was not possible to pull the unfiltered droplet through the obstruction using EWOD forces. Instead, an enabling droplet was merged with the unfiltered droplet across the obstruction (FIG. 5 b) and the almagamated droplet was manipulated so that fluid from the unfilted droplet could pass the obstruction, while the particles could not (FIG. 5). Provided the width of the obstruction is less than twice the deformation of the interface in the opening in the obstruction, the portion of the leading interfaces that exists above the actuating electrode of the droplets will merge within the pore of the obstruction. If a small channel exists in the obstruction the air between the droplets will escape from the pore, and the unfiltered and enabling droplets will merge (FIG. 5 b). Once these droplets have merged, the amalgamated droplet can be pulled through the obstruction by applying an EWOD force on the interface of the amalgamated droplet on the enabling side of the obstruction (FIG. 5 b-f). This will allow fluid or particles smaller than the pore size in the obstruction to pass, but particles in the droplet that are larger than the pore size will be filtered out. Filtration of particles is demonstrated experimentally in FIG. 5, while separation of particles by size is shown in FIG. 7. As the fluid is being pulled through the obstruction a trailing droplet can be added to the unfiltered side of the obstruction. This technique can be used for removing unbound material from the fluid surrounding particles in droplet based microfluidic devices, and replacing that fluid with washing buffer or some other reagent. Once the process is complete, the droplets can be separated on the enabling side of the obstruction (FIGS. 5 f,g, 7 f) and manipulated as required.

In another embodiment of the invention, the physical obstruction is again used as a means of filtering particles from droplets in a droplet based microfluidic device. The device would consist of an array of at least two electrodes, with the obstruction oriented to block the motion of the droplet along the array of electrodes. Here, the droplet is unconfined, but sits atop a substrate patterned with an array of electrodes that act as both actuation and ground electrodes. The obstruction is permeable with a pore size less than or equal to the droplet diameter. The height of the obstruction is sufficient to prevent fluid from passing by travelling over the obstruction. The obstruction can be fabricated from a number of materials, including but not limited to polymers (i.e. PDMS, Su-8), ceramic materials and sintered metals, the obstruction could also be etched out of the substrate of the device (i.e. glass, silicon, quarts, lithium niobate, etc.). Initially, unfiltered droplets exist on one side of the obstruction and an enabling droplet exists on the other side of the obstruction. The unfiltered droplets are seeded with at least one type of particle whose size is larger than the pore size in the obstruction. Again, particles can be man-made or biological in nature. The device may also include control circuitry to automate droplet manipulation. The unfiltered and enabling droplets are manipulated toward the physical obstruction from opposite sides. Again, an enabling droplet is used to pull the droplet passed the obstruction. Once these droplets have merged, the amalgamated droplet can be pulled through the obstruction by applying a force on the interface of the amalgamated droplet on the enabling side of the obstruction. This will allow fluid to pass the obstruction, but the particles in the droplet will be filtered out. As the fluid is being pulled through the obstruction, a trailing droplet can be added to the unfiltered side of the obstruction. This technique can be used for removing unbound material from the fluid surrounding particles in droplet based microfluidic devices, and replacing that fluid with washing buffer or some other reagent. Once the process is complete, the droplets can be separated on the enabling side of the obstruction and manipulated a required.

In another embodiment, this invention can be used as an interface between channel based and discrete flows in microfluidic devices. The device would consist of at least one microfluidic channel (for channel based flow) and an array of at least two addressable electrodes (for discrete flow). A porous obstruction would exist at the interface between the channel and the electrode array (FIG. 8 a). The obstruction can be fabricated from a number of materials, including but not limited polymers (i.e. PDMS, Su-8), ceramic materials and sintered metals, the obstruction could also be etched out of the substrate of the device (i.e. glass, silicon, quarts, lithium niobate, etc.). The maximum size of the pores in the obstruction would be limited by the ability of the surface tension force across the interface in the pore to prevent deformation of the interface as a result of the pressure in the channel. The device may again include control circuitry for the automation of droplet manipulation. The device also includes some method of driving the single phase flow (i.e. pressure driven flow, displacement of fluid, electroosmotic flow etc.). As fluid is moving through the microchannel, the enabling droplet is manipulated to the obstruction that acts as an interface between the channel based and discrete flows. Again the obstruction must be thin enough to allow the leading edge of the enabling droplet to merge with the interface of the channel based flow. If a small channel exists in the obstruction the air between the droplets will escape from the pore, the enabling droplet will merge with the flow in the channel and the far interface of the enabling droplet is pulled away from the obstruction using a discrete flow actuator. This causes some portion of the single phase flow to be drawn out into the discrete flow region of the device (FIG. 8 b-d). At this point, the fluid can be severed from both the enabling droplet and the single phase flow, which will create a discrete portion of the single phase flow (FIG. 8 e,f). The process can be repeated to reduce contamination from the enabling droplet. The process can be reversed to push the droplet back into the single phase flow. In some cases, an actuator may be used to create a void in the channel based flow by deforming the channel structure or by physically parting the fluid itself. If the fluid in the channel is an inert medium (i.e. silicon oil), it may be possible to draw the droplet into the channel by applying a force to the interface between the fluids.

### BRIEF DESCRIPTION OF THE FIGURES

FIG. 1 Sketch of the experimental facility used in this investigation with exploded cross-sectional view of the EWOD device.

FIG. 2 Images showing (a) of an example of a porous obstruction with a pore size of 32 μm and exploded views of a single pore in an obstruction (b) before and (c) after Parylene coating with pore sizes (l_{P}) of 10 and 7 μm, respectively.

FIG. 3 Sketches showing (a) a vertical cross section of an EWOD filtration device, (b) an exploded horizontal cross section of the fluid merging in the pore of the obstruction, and (c) a vertical cross section of the amalgamated droplet being pulled through the filter.

FIG. 4 Experimental images of the droplet being drawn passed an obstruction with a 2 μm pore size. The droplets are (a-b) moved to the obstruction from opposite sides and (c) merged across the obstruction before (d-h) being pulled entirely through. The contrast between the droplet and the device was enhanced in Photoshop.

FIG. 5 Experimental images of droplet filtration using an obstruction with a pore size of 32 μm. A (a,b) particle laden droplet is merged with an enabling droplet across the obstruction before (c-f) fluid is pulled through the obstruction and (g,h) the droplet is split with fluid on one side and particles on the other. The contrast between the droplet and the device was enhanced in Photoshop.

FIG. 6 Experimental images of a particle laden droplet disengaging from an obstruction with a pore size of 32 μm. The contrast between the droplet and the device was enhanced in Photoshop.

FIG. 7 Experimental images of separation of particles by size using an obstruction with a pore size of 72 μm. A (a,b) droplet containing 1 and 100 μm particles is merged with an enabling droplet across the obstruction before (c,d) fluid is pulled through the obstruction. Introduction of (e) an additional washing droplet further recess the concentration of 1 μm particles before (f) the droplet is split and moved to one side of the filter. The process can be repeated to further reduce the concentration of 1 μm particles.

FIG. 8 Sketch of a top down view of the invention being used as an interface between continuous and discrete portions of a microfluidic device. Shown here are (a) the initial position, (b) the enabling droplet merging with the single phase flow in the porous obstruction, a finger of fluid being (c) drawn and (d) separated from the flow forming (e) an amalgamated droplet which is then (f) split into two separate droplets.

### DETAILED DESCRIPTION OF THE FIGURES

Although the proposed invention is compatible with a number of discrete flow microfluidic platforms, experimental validation was carried out using EWOD devices.

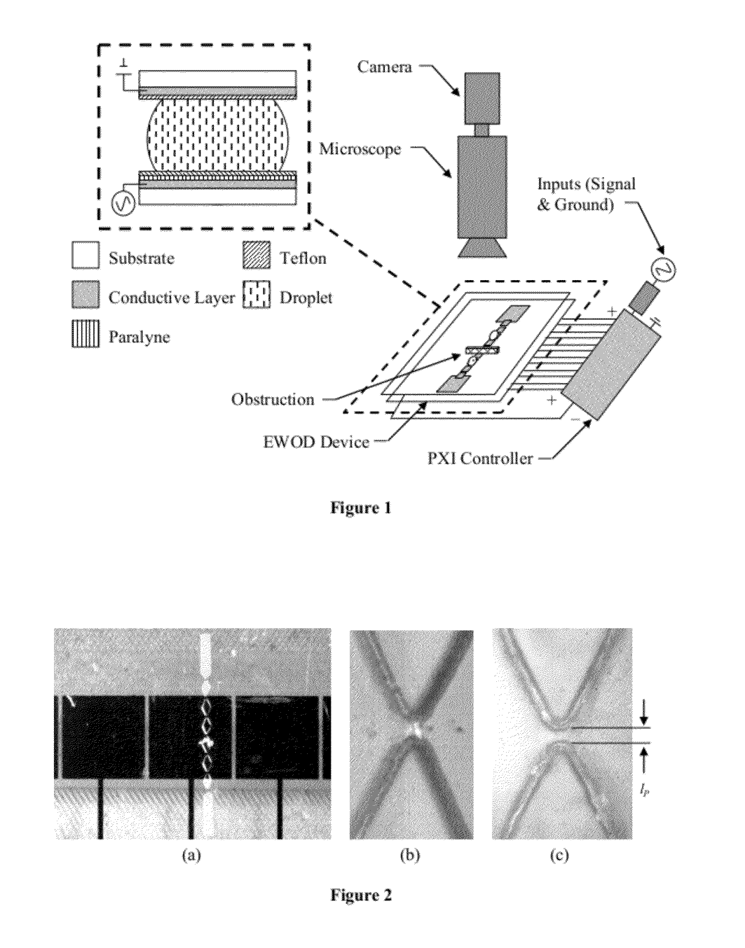

Experimental results presented here were performed using an electrowetting on dielectric (EWOD) device similar to that shown in FIG. 1. The EWOD device consisted of two silica glass slides. The upper and lower slides were approximately 25×75 mm and 75×75 mm, respectively. Both slides were cleaned using an organic solvent, before fabrication. The lower slide was coated with a conductive layer of chromium and gold that was patterned into an array of square electrodes with a side length of 1.5 mm separated by 60 μm. After fabrication of the obstruction, the lower slide was coated with a dielectric Parylene layer and a hydrophobic Teflon layer. The upper slide had an ITO layer which was coated with Teflon. The thicknesses of the chromium, gold, ITO, Parylene, and the Teflon layers were approximately 10 nm, 100 nm, 150 nm, 2 μm, and 50 nm, respectively. The Parylene and Teflon layers above the electrical bond pads were manually scratched away to provide electrical contact.

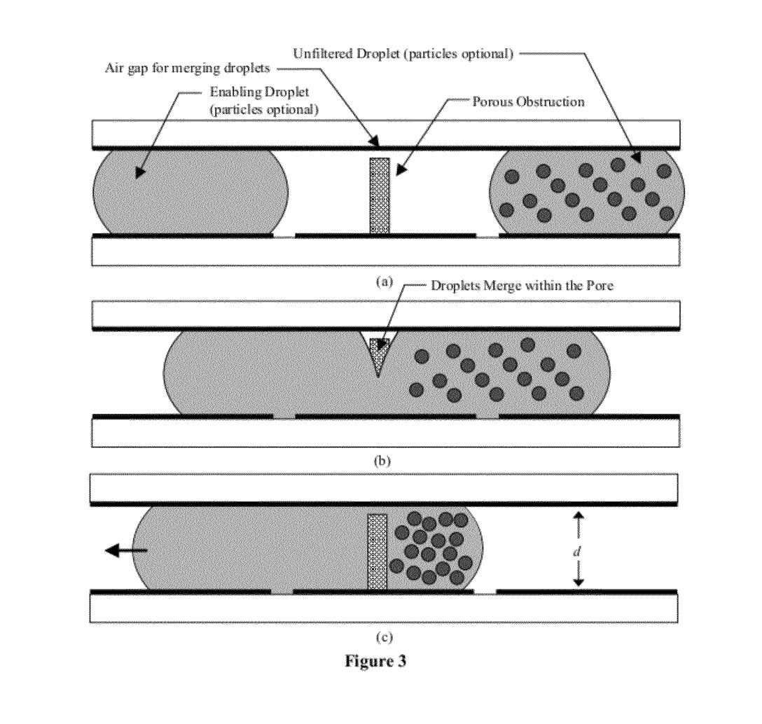

The porous obstruction was situated on an addressable electrode so that EWOD forces would act on the leading interface of both droplets as they approached the obstruction (FIG. 2 a). The obstruction consists of a series of diamond shaped protrusions with thicknesses of either 300 or 150 μm. The pore size (l_{P}) between these protrusions was varied between 2 and 75 μm (FIG. 2). The protrusions were made by depositing a 150 mm thick layer of SU-8 which was patterned using standard photolithographic techniques. Spacing between the two substrates was achieved using two pieces of double sided 3M scotch tape, which resulted in a gap distance of approximately 180 μm. The small gap between the upper surface of the obstruction and the upper substrate allows the air between the two droplets to escape when they merge (FIG. 3).

The confined droplets in this investigation are composed of a 100 μM solution of the fluorescent dye Rhodamine B and deionized water. The Rhodamine B was added so the droplet would be more clearly visible in the recorded images. Droplets were deposited onto the bottom substrate using a pipette before being covered by the upper plate. In some cases, droplets were seeded with soda-lime glass microspheres purchased from MO-SCI Specialty Products with diameters rang from 106 to 125 μm.

Selective application of the electric field was achieved with a control system consisting of a National Instruments PXI 8195 controller, a PXI 2529 matrix-switching device, an Agilent 33120A signal generator, and a custom amplifier similar to that used in [15,16]. Output channels were connected to bond pads for each addressable location on the EWOD device using a custom fixture. Electrical connections were automated using Labview Real Time 8.2. The applied voltage was varied between 110-120 V_{RMS} and the frequency was fixed at 10 kHz. Images of droplet motion were taken using a Canadian Photonics Laboratory MS5K black and white camera (1280×1020 pixels) that was connected to a Leica MZ16F fluorescence stereomicroscope.

For the range of pore sizes considered here, experimental results showed that it was not possible for a single droplet to be drawn through the obstruction. For a practical filter, the pore size in the obstruction can be no larger than the gap distance. The pressure across a curved three dimensional interface is

P=γ(1/r+1/R), (1)

where r and R are the principal radii of curvature. Normally, in an EWOD device R>>r, so the pressure from the second term can be neglected. The asymmetric deformation of the interface from EWOD manipulation results in a difference in the pressure across the leading (P_{L}=−γ/d(cos θ₀+cos θ_{V})) and trailing interfaces (P_{T}=γ/d(2 cos θ₀)). Therefore, the pressure difference across the droplet is

P_{T}−P_{L}=γ/d(cos θ_{V}−cos θ₀), (2)

where d is the gap height (FIG. 3c), θ is the contact angle and the subscripts V and 0 denote contact angles above active and inactive electrodes, respectively. When the droplet encounters the obstruction with a comb type filter, the pressure from the second principal radius on the leading interface cannot be neglected and the pressure across that interface becomes P_{L}=−γ/d(cos θ₀+cos θ_{V})−γ/l_{P} (2 cos θ₀), where l_{P} is the size of the pore in the obstruction (FIG. 2). In this case, the pressure difference across the droplet becomes

P_{T}−P_{L}=γ/d(cos θ_{V}−cos θ₀+2 cos θ₀(d/l_{P})). (3)

Since θ₀>π, cos θ₀<0, a reduction in the pore size also reduces the driving pressure across the droplet. The limiting practical case occurs when l_{P}=d where (3) becomes

P_{T}−P_{L}=γ/d(cos θ_{V}+cos θ₀). (4)

For water in an EWOD device, θ₀≈120°, θ_{V}≈90°. Therefore, (4) will be less than zero and the pressure on the leading edge of the droplet is greater than that on the trailing edge when the droplet is in contact with the obstruction. The droplet will not be driven past the obstruction in this case.

Filtration of droplets in EWOD devices could also be accomplished by constricting the flow with an obstruction that extends up from either the top or bottom substrate. In this case, the pressure across the droplet becomes

P_{T}−P_{L}=γ/d((d/l_{VP})(cos θ_{V}−cos θ₀)−2 cos θ₀), (5)

where l_{VP} is the vertical distance between the protrusion and the substrate. With water in a typical EWOD, the pressure drop in equation (5) will be negative if the opening in the obstruction is smaller than approximately half the gap distance. This limits the range of viable pore sizes and makes filtration of small particles, like animal cells, impractical.

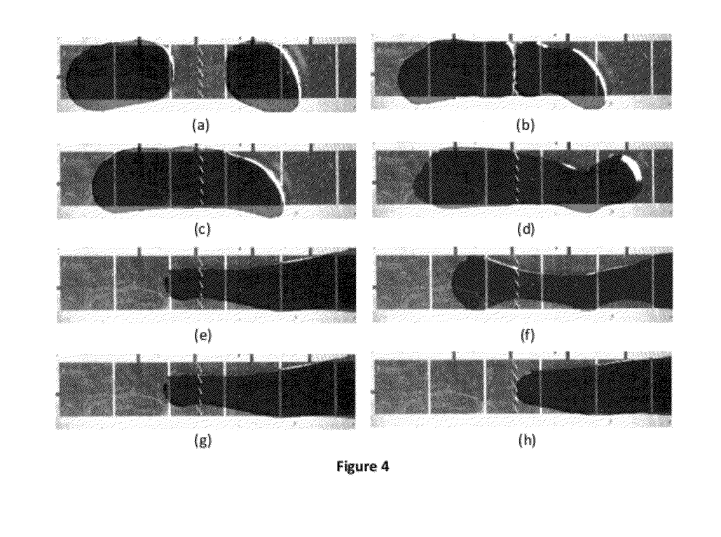

Analytical results show that a single droplet cannot be drawn through an obstruction with a pore size smaller than half the gap distance in an EWOD device (equations 4-5). However, it is possible to use an enabling droplet to overcome the loss of driving force on the interface when it encounters an obstruction. The EWOD force applied on the droplet will deform the interface even if it is not sufficient to pull the droplet through the obstruction (FIG. 3b). If two droplets meet at an obstruction that is sufficiently thin, the interfaces will merge within the pore (FIG. 4 a-c). The amalgamated droplet can then be pulled past the obstruction by applying the EWOD force on an interface that is not deformed by the filter (FIG. 4 d-h). This process was possible for a wide range of pore sizes from approximately half (72 μm) to two orders of magnitude below (2 μm) the gap distance. Smaller pore sizes were not tested. This suggests that the method proposed here is suitable for particle filtration in EWOD devices.

After manipulating droplets past obstructions with a wide range of pore sizes, experiments were performed to demonstrate mechanical filtration in EWOD devices. In filtration experiments, a particle laden droplet carrying soda-lime glass microspheres was merged with an enabling droplet across porous obstructions with pore sizes between 2 and 72 μm (FIG. 5 a,b). Fluid in the droplet was then pulled through the filter via EWOD manipulation (FIG. 5 c-f). During this process, particles were pulled toward the filter but they could not pass. The particle free fluid was then separated from the amalgamated droplet (FIG. 5 g,h). The wide range of effective pore sizes suggests that it should be possible to sort particles by size using this technique. The success of this technique at small pore radii will lead to the use of smaller beads in EWOD immunoassays. This will increases the surface area available for reagent binding and increase the sensitivity of these devices. Pore sizes smaller than animal cells are also of practical importance. The 2 μm pore size used here is smaller than that used for filtration of white blood cells in continuous flow microfluidic devices [14,P10]. This suggests that the method presented here is suitable for the filtration of animal cells from droplets in EWOD devices.

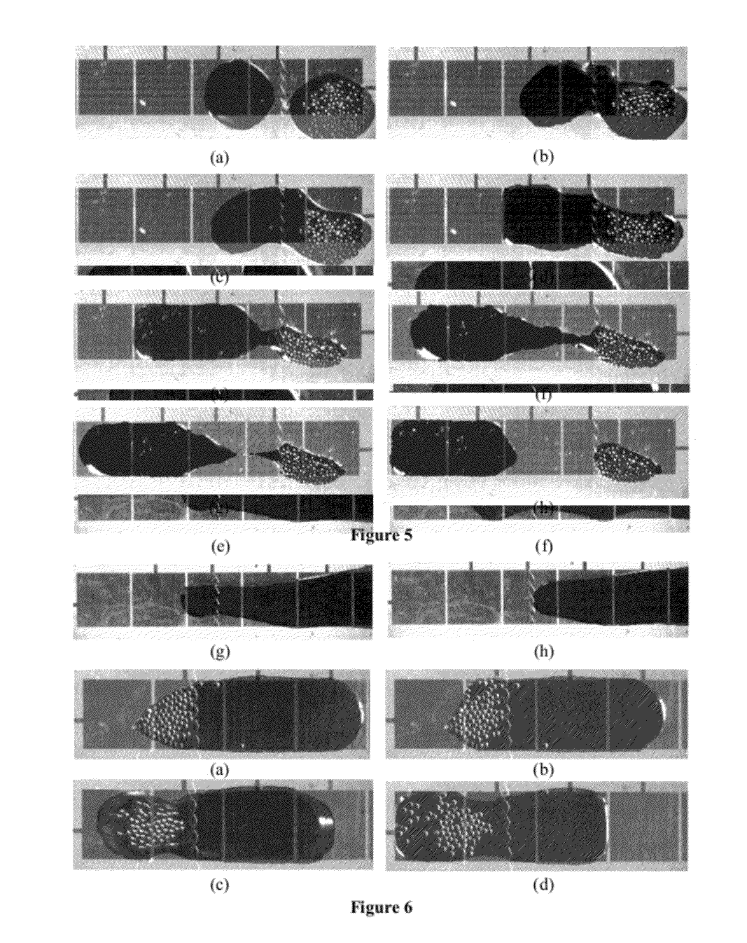

Resuspension of particles can prove difficult in microfluidic devices [i.e. 10-12]. Surface forces become dominant at small length scales and particles tend to adhere more strongly to surfaces. This was not the case in this investigation. Experiments were performed where particles were pulled up to and away from the obstruction. As the droplet was pulled away from the obstruction, particles were resuspended in the flow without surfactants (FIG. 6). This may make this filtration method more suitable for biological material than other means that require the use of these chemicals.

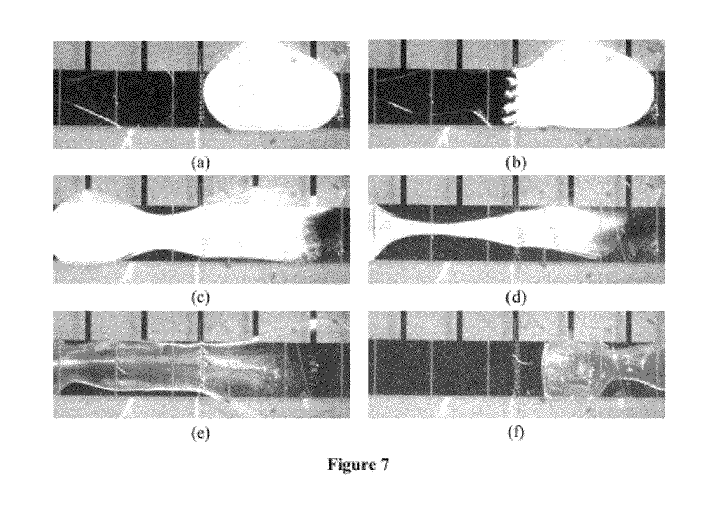

The wide range of effective pore sizes seen in this investigation suggests that it is possible to sort particles by size using this technique. This capability was demonstrated by filtering a droplet containing 110 μm particles and 1 μm fluorescent particles with a 150 μm wide filter with a pore size of 72 μm (FIG. 7). Penetration of the small particles beyond the filter occurs almost immediately after merger and continues as fluid is pulled through using EWOD (FIG. 7 b-d). The trailing edge of the particle laden droplet is then resupplied with a fresh droplet of deionized water to further reduce the concentration of 1 μm particles before the droplet is split and detached from the filter (FIG. 7 e,f). This result demonstrates that it is possible to separate particles by size in EWOD devices using the proposed mechanical filtration method.

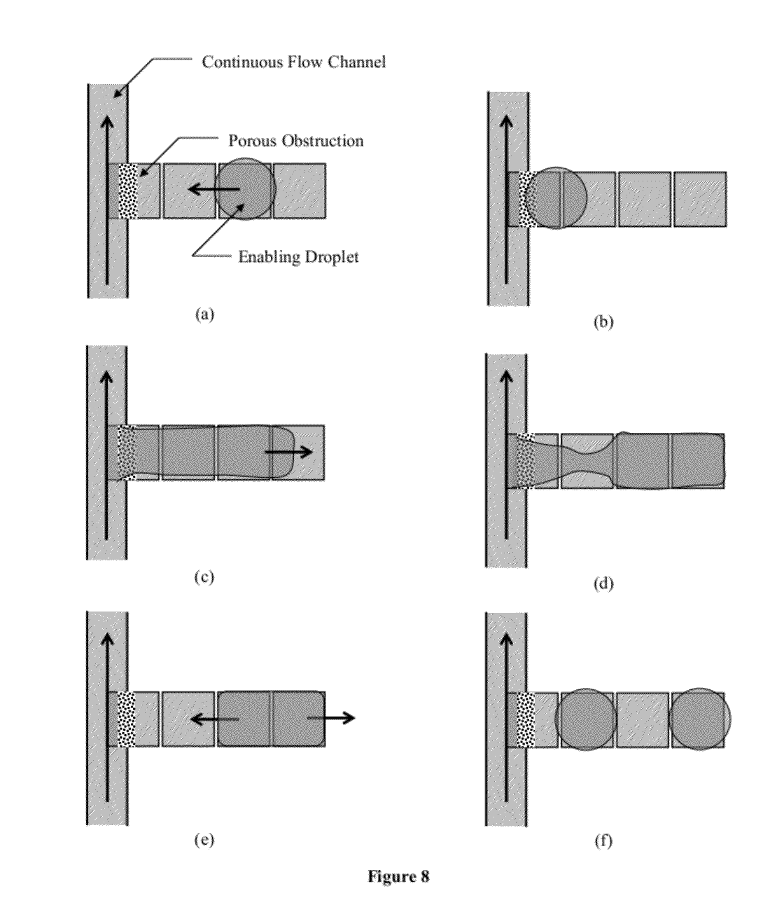

Finally, a sketch of the device as an interface between continuous and droplet based portions of a microfluidic device is shown in FIG. 8. Initially, an amalgamated droplet exists in the discrete portion of the device which is separated from a fluid carrying microchannel by a porous obstruction. As fluid moves through the microchannel, the enabling droplet is driven to the obstruction where it merges with the continuous flow (FIG. 8 b). After the merge, a finger of fluid is drawn through the obstruction and into the discrete portion of the chip (FIG. 8 c) before being severed to create a large droplet solution of the amalgamated droplet and fluid from the microchannel (FIG. 8 d,e). These droplets are then separated (FIG. 8 f) to create a droplet with a high concentration of fluid from the channel. The process can be repeated to increase the concentration of channel fluid in the final droplet. The process can be reversed to push the droplet back into the single phase flow. In some cases, an actuator may be used to create a void in the single phase fluid by deforming the channel structure or by physically parting the fluid itself. If the fluid in the single phase channel is an inert (i.e. silicon oil), it may be possible to draw the droplet into the channel using surface tension forces such as those generated in EWOD.

1. A droplet based microfluidic device and process that enables fluid to pass into or out of a droplet past a porous obstruction.

2. The device claimed in 1 which is made up of at least one porous obstruction, two substrates and at least one confined droplet that passes at least one obstruction via a second enabling droplet that merges with the first droplet across the obstruction.

3. The device claimed in 3 where the droplets are manipulated by electrowetting, electrowetting on dielectric, surface acoustic waves, electro-osmotic flow, electrohydrodynamics, electrostatic forces, flow in the surrounding medium, or pressure.

4. The device claimed in 4 where at least one of the droplets contains at least one type of natural or man-made particle that is larger than the pore size in the obstruction so that fluid may pass the obstruction but at least one size of particle is filtered out, or where one or more particle sizes are filtered out by one or more obstructions.

5. The device claimed in 5 where the obstruction is formed by:
a. Depositing a polymer and patterning it using known methods including photolithography or micromachining
b. Patterning the existing substrate using known methods including photolithography or micromachining
c. A porous material (i.e. sintered ceramic, sintered metal, sintered polymer, porous stone, etc.)

6. The device claimed in 5 where an air gap is provided so that air trapped between the enabling and unfiltered droplets can be removed while the droplets merge.

7. The device claimed in 1 which is made up of at least one porous obstruction, two substrates and at least one sessile (or uncovered) droplet that passes at least one obstruction via a second enabling droplet that merges with the first droplet across the obstruction.

8. The device claimed in 7 where the droplets are manipulated by electrowetting on dielectric, surface acoustic waves, electro-osmotic flow, electrohydrodynamics, electrostatic forces, flow in the surrounding medium, or pressure.

9. The device claimed in 8 where at least one of the droplets contains at least one type of natural or man-made particle that is larger than the pore size in the obstruction so that fluid may pass the obstruction but at least one size of particle is filtered out, or where one or more particle sizes are filtered out by one or more obstructions.

10. The device claimed in 9 where the obstruction is formed by:
a. Depositing a polymer and patterning it using known methods including photolithography or micromachining
b. Patterning the existing substrate using known methods including photolithography or micromachining
c. A porous material (i.e. sintered ceramic, sintered metal, sintered polymer, porous stone, etc.)

11. The device claimed in 1 where at least one porous obstruction acts as an interface between a microchannel containing single- or multi-phase fluid and a discrete flow and fluid is drawn from the microchannel using an enabling droplet on the discrete flow side of the obstruction.

12. The device claimed in 11 where the fluid drawn from the microchannel is made into a separate discrete droplet.

13. The device claimed in 12 where the droplet creation phase is repeated at least once to increase the concentration of the fluid from the microchannel in the final droplet.

14. The device claimed in 13 where natural or man-made particles exist in either the microchannel or in the droplet based flow.

15. The device claimed in 14 where at least one particle type is larger than the pore size in the obstruction so that particulate is filtered during droplet creation.

16. The device claimed in 11 where droplets merge with the continuous flow and fluid from within the droplet passes into the microchannel to create a single- or multi-phase flow. Droplets can be inserted into a void in the microchannel created through deformation of the channel by application of a direct force applied via electrowetting, electrowetting on dielectric, surface acoustic waves, electro-osmotic flow, electrohydrodynamics, electrostatic forces, flow in the surrounding medium, or pressure

17. The device claimed in 16 where natural or man-made particles exist in either the continuous flow or in the droplet based flow.

18. The device claimed in 17 where at least one particle type is larger than the pore size in the obstruction so that particulate is filtered as the fluid in the droplet enters the continuous flow.
